(19) United States
(12) Patent Application Publication
(10) Pub. No.: US 2024/0264091 A1
(43) Pub. Date: Aug. 8, 2024

(54) METHOD FOR INSPECTING VIA HOLE OF WAFER

(71) Applicant: GOOIL ENGINEERING CO., LTD, Gyeongsangbuk-do (KR)

(72) Inventors: Seung Gyun Back, Gyeongsangbuk-do (KR); Jae Yeol Lee, Daegu (KR); Ho Cheol Shin, Daegu (KR); Dae Hwan Kim, Gyeongsangbuk-do (KR)

(73) Assignee: GOOIL ENGINEERING CO., LTD, Gyeongsangbuk-do (KR)

(21) Appl. No.: 18/624,040

(22) Filed: Apr. 1, 2024

Related U.S. Application Data
(63) Continuation of application No. PCT/KR2021/018078, filed on Dec. 2, 2021.

(30) Foreign Application Priority Data
Oct. 6, 2021 (KR) 10-2021-0132616

(51) Int. Cl. G01N 21/95; G01B 11/12; G03H 1/00; H01L 21/66; H01L 21/67; H01L 21/677

(52) U.S. Cl. CPC G01N 21/9503; G01B 11/12; G03H 1/0005; H01L 21/67288; H01L 21/67766; H01L 21/67778; H01L 22/12; G03H 2001/005

(57) ABSTRACT

Provided is a method for inspecting whether the shape and the depth of a via hole formed in a wafer are defective. The method includes a process of receiving three-dimensional image information of the via hole formed in the wafer, a process of detecting an edge of the via hole by using the received three-dimensional image information and an edge detection algorithm, a process of determining whether the detected edge is within a set range, thereby determining whether the shape of the via hole is defective, a process of dividing a three-dimensional image of the via hole generated from the three-dimensional image information of the via hole into at least two regions when the detected edge is within the set range, and a process of determining whether a volume of each divided region is within a set range, thereby determining whether the depth of the via hole is defective.

### CROSS-REFERENCE TO RELATED APPLICATIONS

This is a continuation of PCT international application PCT/KR2021/018078 filed on Dec. 2, 2021, which claims the priority of Korean Patent Application No. 10-2021-0132616 filed Oct. 6, 2021, which are incorporated herein by reference in their entirety.

### TECHNICAL FIELD

The present disclosure relates to a method for inspecting a via hole formed in a wafer. More particularly, the present disclosure relates to a method for measuring and inspecting whether the shape and the depth of a via hole formed in a wafer are defective.

### BACKGROUND

Recently, as small, multi-functional, and thin electronic products are required, 3D packaging processes such as Through Silicon Via (TSV) process, a Package On Package (POP) process, and so on that are next-generation semiconductor technologies are attracting attention in order to improve the integration density of devices in the semiconductor industry.

Particularly, in order to check for a defect during the TSV process, a stacked circuit is manufactured, and then an actual operation test is performed, or a sample is destroyed and the determined by using an equipment such as a Scanning Electron Microscope (SEM) and so on.

Although a non-contact/non-destructive method using a confocal microscope, a WSI, and so on is used, there is a limit in mounting the stacked circuit on an in-line equipment in securing three-dimensional image information due to a method of scanning a cross-sectional place in a Z-axis.

In order to solve this problem, a sample test-level inspection using a Digital Holographic Microscope (DHM) has recently been performed. However, since an inspection region to be inspected by the DHM is very small compared to a wafer region to be inspected, the sample test-level inspection is not actually applied to a semiconductor inspection line.

In addition, a method capable of determining whether a via hole formed in a wafer is accurately formed according to the intention of a designer is required.

Accordingly, in order to solve the problems described above, the present applicant has provided the embodiments of the present disclosure, and as related conventional technology literature, ‘OPTICAL MEASUREMENT OF THE APERTURE DIMENSIONS IN THE WAFER’ is disclosed in Korean Patent No. 10-2228029.

The present invention is associated with the following research project conducted in South Korea. Ministry name: Ministry of Science and ICT; Project management agency name: Institute for Information & communication Technology Planning & evaluation (IITP); Research project name: Hologram core technology development; Research task name: Hologram-based measurement and inspection demonstration; Contribution rate: 1/1; Name of project carrying out organization: Gooil Engineering Co., Ltd; and Research project period: 2022. 04. 01-2025. 12. 31 (45 months).

### BRIEF SUMMARY

Accordingly, the present disclosure has been made keeping in mind the above problems occurring in the related art, and an objective of the present disclosure is to provide a wafer inspection system configured such that a worker can easily perform a process of supplying a wafer and a process of generating and controlling a three-dimensional image in order to determine whether the wafer is abnormal, the wafer inspection system being configured such that whether the wafer is abnormal is capable of being determined with high accuracy.

In addition, the present disclosure has been made keeping in mind the above problems occurring in the related art, and an objective of the present disclosure is to provide a method for inspecting whether the shape and the depth of a via hole formed in a wafer are defective.

In order to realize the objectives described above, according to the present disclosure, there is provided a method for determining whether the shape and the depth of a via hole formed in a wafer are defective by using a program embedded in a wafer inspection system, the method including: a process of receiving three-dimensional image information of the via hole formed in the wafer; a process of detecting an edge of the via hole by using the three-dimensional image information that is received and by using an edge detection algorithm; a process of determining whether the edge that is detected is within a set range, thereby determining whether the shape of the via hole is defective; a process of dividing a three-dimensional image of the via hole generated from the three-dimensional image information of the via hole into at least two regions when the edge that is detected is within the set range; and a process of determining whether a volume of each divided region is within a set range, thereby determining whether the depth of the via hole is defective.

In the wafer inspection system according to the present disclosure, since the configuration in which the wafer is pulled out from the cassette placed in the load port or the wafer is inserted into the cassette in the automated manner, so that the wafer transferring process may be rapidly performed.

In addition, in the wafer inspection system according to the present disclosure, since the configuration in which the wafer is capable of being continuously moved in the left and right directions or the front and rear directions in response to the imaging and inspection region of the Digital Holographic Microscope (DHM) is provided, so that whether the wafer is abnormal is capable of being accurately identified by the three-dimensional image information of the wafer through the holographic image.

In addition, in the wafer inspection system according to the present disclosure, since the configuration in which the wafer to be inspected is transferred by using the rotation stage, the first stage, and the second stage is provided, the transferring accuracy of the wafer may be increased. Furthermore, when a defect occurs in each stage, a process of replacing the defective stage is reduced and the cost thereof is reduced.

In addition, in the wafer inspection system according to the present disclosure, since the configuration in which the rotation stage where the wafer is seated is rotated and transferred by the first stage and the second stage is provided, a position at which the wafer is initially placed is capable of being freely set in response to a position of the wafer transferring portion.

In addition, in the method for inspecting the via hole formed in the wafer according to the present disclosure, by dividing the via hole formed in the wafer into multiple regions and by using each volume of the divided regions, whether the shape and the depth of the via hole are defective may be accurately determined compared to an existing method.

### BRIEF DESCRIPTION OF DRAWINGS

FIG. 1 is a perspective view illustrating a wafer inspection system according to an embodiment of the present disclosure.

FIG. 2 is a perspective view illustrating an overall configuration of a wafer transferring portion according to an embodiment of the present disclosure viewed from the rear.

FIG. 3 is a plan view of the wafer transferring portion illustrated in FIG. 2.

FIG. 4 is a perspective view illustrating a wafer inspection portion according to an embodiment of the present disclosure.

FIG. 5 is a plan view of the wafer inspection portion illustrated in FIG. 4.

FIG. 6 is a side view of the wafer inspection portion illustrated in FIG. 4.

FIG. 7 is a view illustrating a state in which a wafer is placed on a rotation stage according to an embodiment of the present disclosure.

FIG. 8 is a perspective view illustrating a state in which the rotation stage according to an embodiment of the present disclosure is disposed below an optical module.

FIG. 9 is a view illustrating a process for determining whether the shape and the depth of a via hole formed in a wafer are defective according to an embodiment of the present disclosure.

FIG. 10 is a view illustrating an example of extracted edges of via holes according to an embodiment of the present disclosure.

FIG. 11 is a view illustrating an example of determining whether shapes of the via holes are defective, according to an embodiment of the present disclosure.

FIGS. 12A and 12B show an example of determining whether the depth of a via hole is defective by using a volume according to an embodiment of the present disclosure.

### DETAILED DESCRIPTION

Advantages and features of the present disclosure, and methods of achieving the same will become apparent with reference to the embodiments described below in detail in conjunction with the accompanying drawings.

However, the present disclosure is not limited to the embodiments disclosed below, but may be implemented in various different forms. The present embodiments are intended to complete the disclosure of the present disclosure and provided to fully inform the skilled in the art to which the disclosure pertains of the scope of the disclosure. The disclosure is defined only by the scope of the claims.

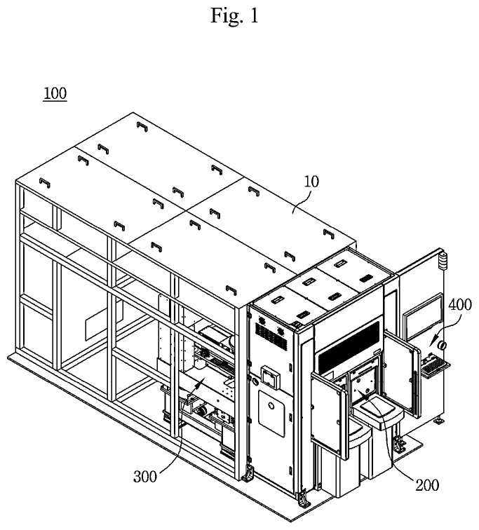

Hereinafter, a wafer inspection system according to an embodiment of the present disclosure will be described in detail with reference to FIG. 1 to FIG. 8. In a description of the present disclosure, a detailed description of related known functions or configurations will be omitted to avoid making the essence of the present disclosure unclear.

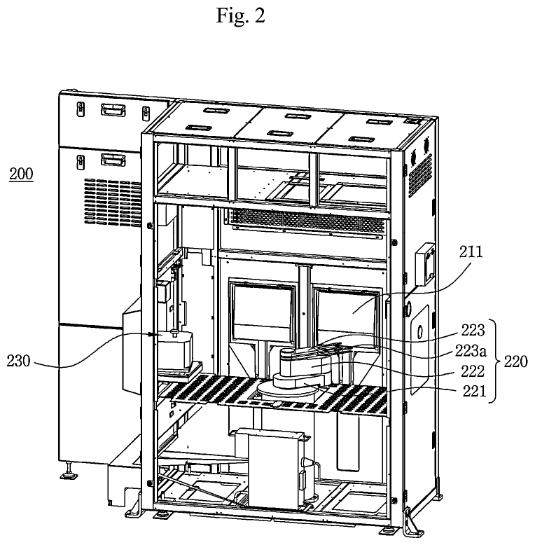

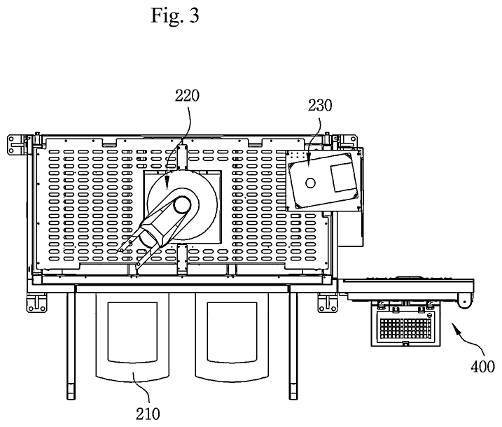

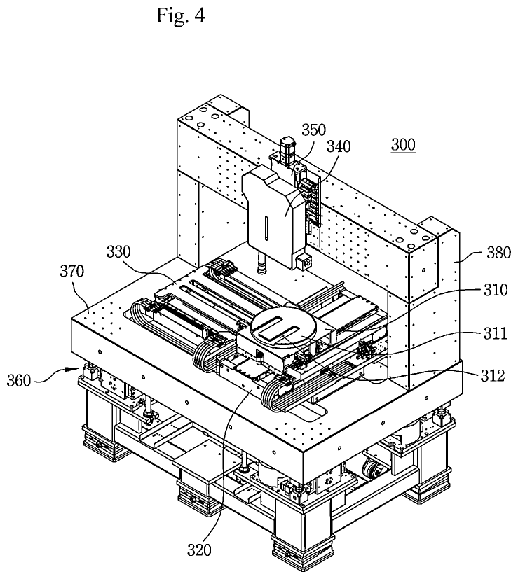

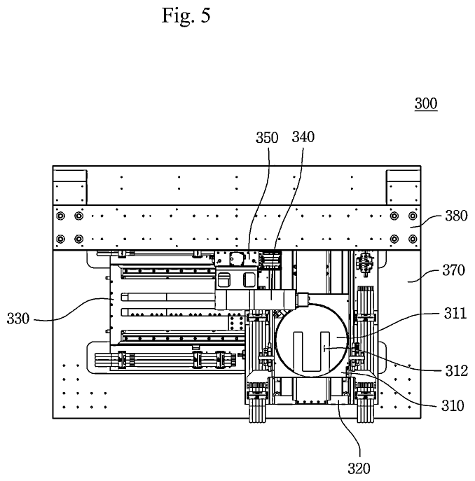

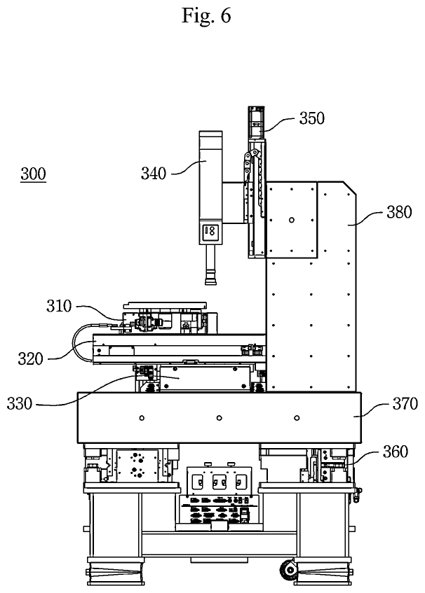

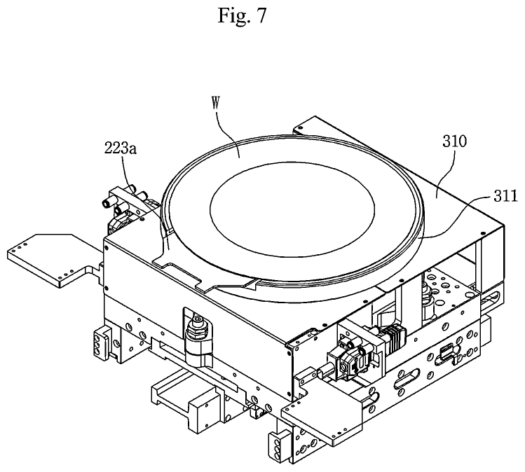

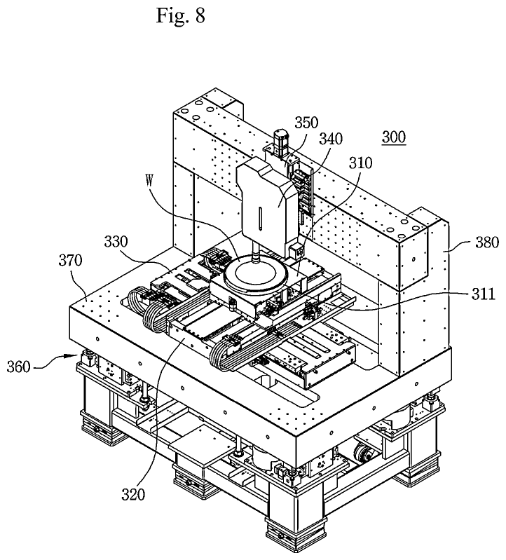

FIG. 1 is a perspective view illustrating a wafer inspection system according to an embodiment of the present disclosure, FIG. 2 is a perspective view illustrating an overall configuration of a wafer transferring portion according to an embodiment of the present disclosure, FIG. 3 is a plan view of the wafer transferring portion illustrated in FIG. 2, FIG. 4 is a perspective view illustrating a wafer inspection portion according to an embodiment of the present disclosure, FIG. 5 is a plan view of the wafer inspection portion illustrated in FIG. 4, FIG. 6 is a side view of the wafer inspection portion illustrated in FIG. 4, FIG. 7 is a view illustrating a state in which a wafer is placed on a rotation stage according to an embodiment of the present disclosure, and FIG. 8 is a perspective view illustrating a state in which the rotation stage according to an embodiment of the present disclosure is disposed below an optical module.

As illustrated in FIG. 1 to FIG. 5, a wafer inspection system 100 according to an embodiment of the present disclosure may include: a wafer transferring portion 200 configured to load and unload a wafer W (see FIG. 7) to be inspected; a wafer inspection portion 300 configured to receive the wafer W from the wafer transferring portion 200 and to secure three-dimensional image information of the wafer by using a holographic image; and a control portion 400 configured to determine whether the wafer W is abnormal on the basis of the three-dimensional image information measured from the wafer inspection portion 300, and control the wafer transferring portion 200 and the wafer inspection portion 300.

First, the wafer transferring portion 200 is a device for loading or unloading the wafer W on the wafer inspection portion 300 to be described later, and is provided inside a housing 10 as illustrated in FIG. 1.

As illustrated in FIG. 2 and FIG. 3, the wafer transferring portion 200 may include: a load port 210 where a cassette (not illustrated) in which the wafer W (see FIG. 7) is stored is placed; a robot arm 220 configured to pick-up the wafer W from the cassette placed in the load port 210; and an alignment portion 230 configured to align the wafer W picked-up by the robot arm 220.

The load port 210 is provided on a first surface of the housing 10, and provides a predetermined space in which the wafer W is capable of being placed. In addition, the load port 210 includes a gate 211 such that the wafer W placed in the space is capable of being transferred inside the housing 10.

In an embodiment of the present disclosure, a pair of load ports 210 is provided on the first surface of the housing 10.

A cassette in which the wafer W to be inspected is stored may be placed in any one load port 210 among the pair of load ports 210, and a cassette in which the inspected wafer W will be stored may be placed in the other load port 210. Therefore, it is preferable that at least one load port 210 is provided on the first surface of the housing 10.

The robot arm 220 may be disposed on an inner first side of the housing 10, and serves to transfer the wafer W disposed in the load port 210.

The robot arm 220 is configured such that the robot arm 220 is capable of being rotated in a direction in which the load port 210 is disposed or in a direction in which the alignment portion 230 is disposed, and is configured such that the robot arm 220 is capable of being rotated in a direction in which the wafer inspection portion 300 to be described later is disposed.

As illustrated in FIG. 2, the robot arm 220 may include: a first arm 221 having a first end in a longitudinal direction thereof connected to a driving shaft such that the first end of the first arm 221 is capable of being rotated; a second arm 222 having a first end in a longitudinal direction thereof connected to a second end of the first arm 221 in the longitudinal direction such that the first end of the second arm 222 is capable of being rotated; and a pick-up arm 223 having a first end in a longitudinal direction thereof connected to a second end of the second arm 222 in the longitudinal direction such that the first end of the pick-up arm 223 is capable of being rotated, the pick-up arm 223 having a second end in the longitudinal direction thereof provided with a pick-up member 223a.

The first arm 221, the second arm 222, and the pick-up arm 223 have configurations capable of being rotated in a first direction or a second direction, and may be individually or simultaneously rotated in various directions. For example, any one configuration of the first arm 221, the second arm 222, and the pick-up arm 223 may be selectively driven or all configurations of the first arm 221, the second arm 222, and the pick-up arm 223 may be simultaneously driven, so that the wafer W may be picked-up from the cassette placed in the load port 210 or the picked-up wafer W may be transferred to the alignment portion 230 or the wafer inspection portion 300.

Meanwhile, the pick-up member 223a provided on a tip end portion of the pick-up arm 233 may be a component that is configured to directly hold the wafer. The pick-up member 223a may have a generally forked shape, and each pick up member 223a may be disposed above and below the wafer W, respectively. That is, the pick-up member 223a may be configured as a pair of pick-up members 223a, and the pair of pick up members 223a is capable of holding the wafer W when the pair of pick-up members 223a is moved adjacent to each other and then is folded.

The alignment portion 230 is a component for aligning the wafer W supported by the pick-up arm 233, and may generally be implemented as a known wafer equipment aligner. A conventional aligner is capable of aligning a wafer by using a CCD camera, an infrared ray sensor, or an ultrasonic sensor.

The wafer transferring portion 200 configured as described above may sequentially perform a process of picking-up the wafer W placed in the load port 210, a process of aligning the picked-up wafer W, and a process of supplying the aligned wafer W to the wafer inspection portion 300.

The wafer inspection portion 300 may be referred to as a device configured to receive the wafer W to be inspected from the wafer transferring portion 200 and to inspect whether the wafer W is abnormal.

As illustrated in FIG. 4 to FIG. 8, the wafer inspection portion 300 according to an embodiment of the present disclosure may include: a rotation stage 310 on which the wafer W to be inspected is seated and which is configured to align the wafer W; a first stage 320 on which the rotation stage 310 is mounted and which is configured to transfer the rotation stage 310 in a front direction or a rear direction; a second stage 330 on which the first stage 320 is mounted and which is configured to transfer the first stage 320 in a left direction or a right direction; and an optical module 340 configured to capture the wafer W placed on the rotation stage 310 and to secure three-dimensional hologram information.

The rotation stage 310 may include a rotation plate 311 which is rotated by receiving a power from a driving portion that is not illustrated and on which the wafer to be inspected is placed.

The rotation plate 311 provides a predetermined area on which the wafer W is capable of being placed.

In addition, in order to fix the wafer W by a vacuum adsorption method, the rotation plate 311 may be manufactured using a porous material. That is, a flow path into which air can flow may be formed on a lower portion of the rotation plate 311. Therefore, when an air pump that is not illustrated is operated, the wafer W may be adsorbed to the rotation plate 311.

In addition, a seating groove 312 may be provided in the rotation plate 311.

The tip end portion of the pick-up arm 223 holding the wafer W may be inserted into the seating groove 312 of the rotation plate 311. Therefore, the seating groove 312 may have the shape corresponding to the shape of the pick-up member 223a provided on the tip end portion of the pick-up arm 223.

As illustrated in FIG. 7, when the pick-up member 223a holding the wafer W is inserted into the seating groove 312 provided in the rotation plate 311, the wafer W may be positioned on an upper surface of the rotation plate 311.

In this state as described above, when the pick-up member 223a of the pick-up arm 223 is slidably moved and is separated from the seating groove 312, the wafer W is capable of being vacuum adsorbed to the rotation plate 311.

The rotation plate 311 may be rotated while the wafer W is adsorbed to the rotation plate 311, and may align an inspection region of the wafer W such that the inspection region of the wafer W corresponds to a lens of the optical module 340 to be described later.

The first stage 320 is provided with a guide rail for moving the rotation stage 310 forward or backward, and the guide rail is connected to the rotation stage 310.

A power source for transferring the rotation stage 310 mounted on the first stage 320 may be configured as a driving motor or a known actuator.

The second stage 330 is provided with a guide rail for transferring the first stage 320 in the left direction or the right direction, and the guide rail is connected to the first stage 320.

Likewise, a power source for transferring the first stage 320 mounted on the second stage 330 may be configured as a driving motor or a known actuator.

The rotation stage 310, the first stage 320, and the second stage 330 described above may be provided on a surface plate 370.

At this time, the second stage 330 may be disposed along a longitudinal direction of the surface plate 370, and the first stage 320 may be disposed along a width direction of the surface plate 370.

The first stage 320 and the second stage 330 serve to transfer the wafer W disposed on the rotation plate 311 along the longitudinal direction or the width direction of the surface plate 370.

That is, as illustrated in FIG. 8, the first stage 320 and the second stage 330 are also configured such that the inspection region of the wafer W to be inspected corresponds to the lens of the optical module 340.

The optical module 340 may be mounted on a support frame 380 provided on the surface plate 370 such that the optical module 340 is capable of being moved upward or downward.

The support frame 380 has a gantry shape and is provided on the surface plate 370, and a center portion of the support frame 380 is provided with a lifting stage 350.

The optical module 340 is mounted on the lifting stage 350, and may be configured as a reflective Digital Holographic Microscope (DHM) configured to generate holographic information using reflective light and to measure three-dimensional image information of the wafer W.

Therefore, the optical module 340 may be moved downward by the lifting stage 350 such that the optical module 340 is moved in a direction in which the wafer W is disposed. Furthermore, the optical module 340 may be moved upward by the lifting stage 350 such that the optical module 340 is moved to an original state.

For reference, the reflective DHM is configured such that light is shined in front of a hologram and a reflected image can be observed in front of the hologram, and has an advantage of having a distinct three-dimensional effect, unlike existing holographic microscopes, so that it can be said that the reflective DHM is suitable for checking whether the wafer W is abnormal.

Meanwhile, the inspection region in which the optical module 340 is capable of securing three-dimensional image information by capturing the wafer W may be a partial area of the total area formed by the wafer W.

That is, an imaging area in which the optical module 340 is capable of securing three-dimensional holographic information may be, for example, 1/30 to 1/40 of the total area formed by the wafer W.

Therefore, it is very important that the wafer W placed on the rotation plate 311 is continuously transferred by using the rotation stage 310, the first stage 320, and the second stage 330 that are described above. In other words, in order to inspect the total area of the wafer having a diameter of 20 cm to 30 cm, a process of continuously and sequentially matching a partial area to be inspected among the total area of the wafer W with the lens of the optical module 340 is required to be performed, and the rotation plate 311, the first stage 320, and the second stage 330 may perform this process.

In addition, it can be said that preventing sway of the wafer W in the process of moving the wafer W is very important in order for the optical module 340 to secure three-dimensional holographic information with high accuracy.

Therefore, a vibration isolating table 360 is provided on a lower corner of the surface plate 370.

The vibration isolating table 360 serves to correct a position of the surface plate 370 to a predetermined position when a shock or vibration caused by an external force occurs on the surface plate 370. Specifically, the tilt of the surface plate 370 may be corrected in a horizontal direction, and the height or the tilt of the surface plate 370 may be corrected such that the wafer W is maintained in a predetermined position from a frictional force or fine vibration generated during the transferring process of the rotation stage 310, the first stage 320, and the second stage 330.

In the wafer inspection portion 300 according to the present disclosure configured as described above, a configuration capable of continuously moving the wafer W in the left and right directions or the front and rear directions in response to the imaging and inspection region of the DHM is provided, so that whether the wafer is abnormal is capable of being accurately identified by the three-dimensional image information of the wafer through the holographic image.

The control portion 400 may receive the three-dimensional image information measured at the wafer inspection portion 300. In addition, from the measurement information, whether the wafer W is abnormal may be identified, and the result of whether the wafer W is abnormal may be transmitted to an inspector.

For example, when an abnormality occurs in the wafer W, the control portion 400 may control the wafer transferring portion 200 such that the wafer W in which the abnormality occurs is separated from the wafer inspection portion 300.

In addition, as another example, when no abnormality occurs in the wafer W, the control portion 400 may control the wafer transferring portion 200 such that the wafer W determined to be a good product is transferred to the load port 210.

The control portion 400 as described above may be provided such that the control portion 400 is disposed on a first side of the wafer transferring portion 200, and may include various control buttons and displays so that the inspector can control driving commands of the wafer transferring portion 200 and the wafer inspection portion 300 and can visually check the three-dimensional image information of the wafer W.

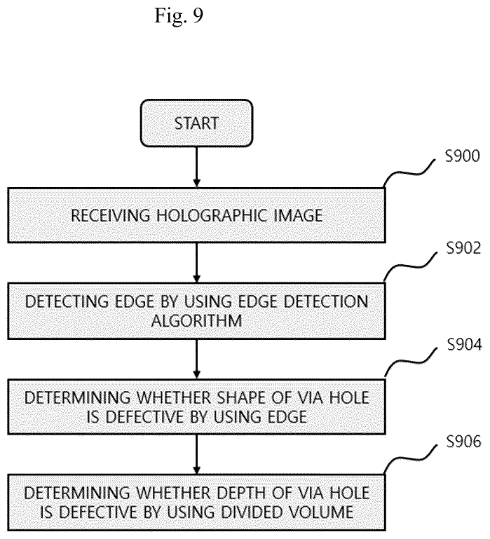

FIG. 9 is a flowchart illustrating a process of determining whether a via hole formed in a wafer is defective according to an embodiment of the present disclosure. Hereinafter, a process of determining whether the shape and the depth of a via hole formed in a wafer are defective according to an embodiment of the present disclosure will be described in detail with reference to FIG. 9.

In an S900 process, the control portion receives a holographic image. As described above, holographic image information is three-dimensional image information of a wafer in which a via hole is formed.

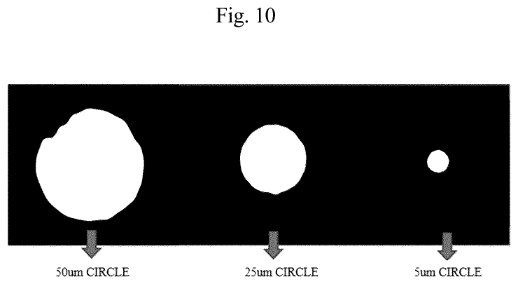

In an S902 process, the control portion detects an edge of a via hole. To this end, the control portion extracts the edge formed in the via hole by using an edge detection algorithm. The edge detection algorithm uses a first edge detection algorithm in which an edge is detected by using a mask coefficient, a second edge detection algorithm in which an edge is detected by using a noise removal using a filter, a detection of a gradient strength and direction applying a horizontal/vertical gradient mask, and a non-maximum suppression by comparing a size of a current pixel and size of an adjacent pixel, and a historical threshold processing, or a third edge detection algorithm in which an edge is detected by using a linear equation and a triangulation function. In addition, an edge formed in the wafer is detected in various manners. FIG. 10 is a view illustrating an example of edges detected by using the edge detection algorithm. FIG. 10 shows a cross-sectional view illustrating via holes having various sizes and shapes.

In an S904 process, the control portion determines whether the shape of the via hole is defective on the basis of the detected edge. The control portion compares the edge detected by the edge detection algorithm with a set edge. In relation to the present disclosure, the control portion compares a radius (or a diameter) of the edge detected by the edge detection algorithm with a radius (or a diameter) of the set edge. When the radius (or the diameter) of the edge detected by the edge detection algorithm is outside the radius (or the diameter) of the set edge, it is determined that the edge is defective. Of course, the set radius has a range rather than a specific value. FIG. 11 is a view illustrating an example of determining whether the shape of the via hole is defective according to an embodiment of the present disclosure. As illustrated in FIG. 11, when the diameter of the detected via hole is outside the set range, it is determined that the via hole is defective.

In an S906 process, the control portion divides a three-dimensional via hole image into multiple regions, calculates a volume of each region, and determines whether the depth of the via hole is defective. As an example, the three-dimensional via hole is divided into three regions, and a volume of each region is calculated. The calculated volume for each region is compared to a set volume range, and whether the depth of the via hole is defective is determined. Of course, the control unit may divide the three-dimensional via hole into three regions or at least four regions, and then may calculate a volume of each region.

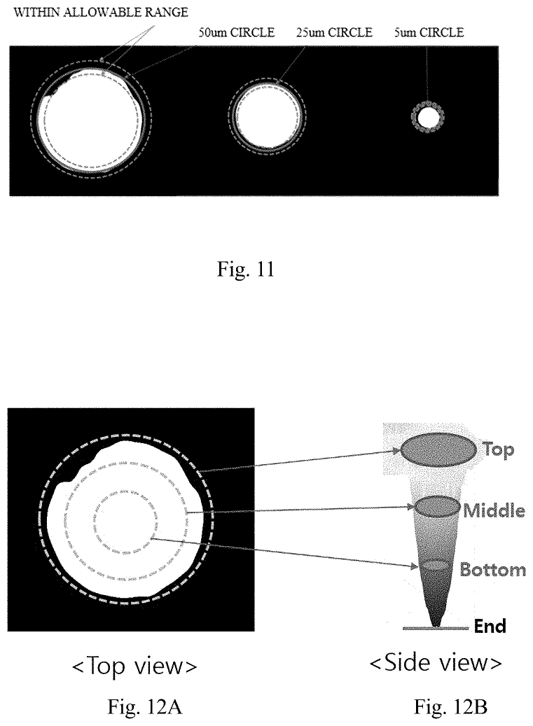

FIG. 12A and 12B illustrate an example of determining whether the depth of the via hole is defective by using a volume according to an embodiment of the present disclosure. In relation to the present disclosure, the volume may be calculated by using a diameter of an upper cross section (e.g., middle) of the divided region, a diameter of a lower cross section (e.g. bottom) of the divided regions, and a length between the upper cross section and the lower cross section of the divided regions. To this end, the control portion calculates the diameter of the upper cross section of the divided regions, the diameter of the lower cross section of the divided regions, and the length between the upper cross section and the lower cross section of the divided regions. In addition, the control portion may calculate the volume of the divided regions in various other manners.

As described above, in the present disclosure, whether the shape of a via hole is defective is primarily determined by using a cross-sectional surface (an edge) of the formed via hole. Then, whether the depth of the via hole is defective is secondarily determined by using a volume of the divided via hole. Furthermore, inspection reliability may be increased by increasing the number of the divided via holes. In addition, in the present disclosure, whether the via hole is defective is not only determined by simply using the shape of the via hole, and whether the depth of the via hole is defective is determined by using the cross-sectional area and the volume.

In addition, in the present disclosure, it is described that the whether the via hole is defective is determined by the control portion, but is not limited thereto. By using a program installed on the wafer inspection system or a program installed on a device connected to the wafer inspection system, whether the via hole is defective may be determined.

Although detailed exemplary embodiments according to the present disclosure have been described so far, obviously, various modifications may be made without departing from the scope of the present disclosure.

Therefore, the scope of the present disclosure should not be limited to the described exemplary embodiments, and should be determined not only by the scope of the claims to be described later, but also by the scope and equivalents of the claims.

The present disclosure relates to a method for inspecting a via hole formed in a wafer. More particularly, the present disclosure relates to a method for measuring and inspecting whether the shape and the depth of a via hole formed in a wafer are defective.

In the method for determining the via hole formed in the wafer according to the present disclosure, by dividing the via hole formed in the wafer into multiple regions and by using each volume of the divided regions, whether the shape and the depth of the via hole are defective may be accurately determined compared to an existing method.

1. A method for determining whether a shape and a depth of a via hole formed in a wafer are defective by using a program embedded in a wafer inspection system, the method comprising:
a process of receiving three-dimensional image information of the via hole formed in the wafer;
a process of detecting an edge of the via hole by using the three-dimensional image information that is received and by using an edge detection algorithm;
a process of determining whether the edge that is detected is within a set range, thereby determining whether the shape of the via hole is defective;
a process of dividing a three-dimensional image of the via hole generated from the three-dimensional image information of the via hole into at least two regions when the edge that is detected is within the set range; and
a process of determining whether a volume of each divided region is within a set range, thereby determining whether the depth of the via hole is defective.

2. The method of claim 1, wherein, in the process of determining whether the edge that is detected is within the set range, whether a radius calculated from the edge that is detected is within the set range is determined.

3. The method of claim 2, wherein the three-dimensional image information is holographic image information.

4. The method of claim 3, wherein the wafer inspection system comprises:
a wafer transferring portion configured to load and unload the wafer to be inspected;
a wafer inspection portion configured to receive the wafer from the wafer transferring portion and to secure three-dimensional image information of the wafer by using a holographic image; and
a control portion configured to determine whether the wafer is abnormal by using the three-dimensional image information measured from the wafer inspection portion, and configured to control the wafer transferring portion and the wafer inspection portion.

5. The method of claim 1, wherein, in the process of dividing the three-dimensional image of the via hole into at least two regions, the three-dimensional image of the via hole is divided into a first region, a second region, and a third region from an upper end of the three-dimensional image, and whether the volume calculated for each divided region is within the set range is determined.

6. A wafer inspection system comprising:
a wafer transferring portion configured to load and unload a wafer to be inspected;
a wafer inspection portion configured to receive the wafer from the wafer transferring portion and to secure three-dimensional information of the wafer by using a holographic image; and
a control portion configured to determine whether the wafer is abnormal by using the three-dimensional information measured from the wafer inspection portion, and configured to control the wafer transferring portion and the wafer inspection portion.

7. The wafer inspection system of claim 6, wherein the wafer transferring portion comprises:
a load port where a cassette in which the wafer is stored is placed;
a robot arm configured to pick-up the wafer from the cassette placed in the load port; and
an alignment portion configured to align the wafer picked-up by the robot arm.

8. The wafer inspection system of claim 7, wherein the robot arm comprises:
a first arm having a first end in a longitudinal direction thereof connected to a driving shaft such that the first end of the first arm is capable of being rotated;
a second arm having a first end in a longitudinal direction thereof connected to a second end of the first arm in the longitudinal direction such that the first end of the second arm is capable of being rotated; and
a pick-up arm having a first end in a longitudinal direction thereof connected to a second end of the second arm in the longitudinal direction such that the first end of the pick-up arm is capable of being rotated, the pick-up arm having a second end in the longitudinal direction thereof provided with a pick-up member.

9. The wafer inspection system of claim 8, wherein the wafer inspection portion comprises:
a rotation stage on which the wafer transferred by the robot arm is seated and which is configured to align the wafer;
a first stage on which the rotation stage is mounted and which is configured to transfer the rotation stage in a front direction or a rear direction;
a second stage on which the first stage is mounted and which is configured to transfer the first stage in a left direction or a right direction; and
an optical module configured to secure the three-dimensional information of the wafer placed on the rotation stage.

10. The wafer inspection system of claim 9, wherein the rotation stage comprises a rotation plate which is configured to be rotated by receiving a power from a driving portion and on which the wafer to be inspected is placed, and a seating groove into which the pick-up member of the pick-up arm holding the wafer is inserted is provided on the rotation plate.

11. The wafer inspection system of claim 9, further comprising a surface plate on which the second stage is mounted, wherein the second stage is disposed along a longitudinal direction of the surface plate, and the first stage is disposed along a width direction of the surface plate and the first stage is mounted on the second stage.

12. The wafer inspection system of claim 11, further comprising a lifting stage provided on a support frame that is provided on the surface plate, the lifting stage being configured to move the optical module upward or downward.

13. The wafer inspection system of claim 11, wherein a vibration isolating table is provided on a lower corner portion of the surface plate.

14. The wafer inspection system of claim 9, wherein the optical module is a reflective Digital Holographic Microscope (DHM) configured to generate holographic information using reflective light and to measure the three-dimensional information of the wafer.
